(19) United States
(12) Patent Application Publication
(10) Pub. No.: US 2016/0343796 A1
(43) Pub. Date: Nov. 24, 2016

(54) CAPACITOR STRUCTURE AND METHOD FOR FORMING THE SAME

(71) Applicant: MediaTek Inc., Hsin-Chu (TW)

(72) Inventors: Bo-Jr HUANG, Hsinchu City (TW); Jia-Wei FANG, Hsinchu City (TW)

(21) Appl. No.: 15/158,814

(22) Filed: May 19, 2016

Related U.S. Application Data
(60) Provisional application No. 62/165,258, filed on May 22, 2015.

(51) Int. Cl. H01L 49/02

(52) U.S. Cl. CPC H01L 28/87

(57) ABSTRACT

A capacitor structure includes first and second interdigitated conductive elements formed over different portions of a semiconductor substrate, and a dielectric layer formed between the first and second interdigitated conductive elements. The first interdigitated conductive element that is formed includes a first base portion and a plurality of first protrusion portions. The second interdigitated conductive element includes a second base portion and a plurality of second protrusion portions. The second protrusion portions of the second interdigitated conductive element are interleaved with the first protrusion portions of the first interdigitated conductive element.

### CROSS REFERENCE TO RELATED APPLICATIONS

This application claims the benefit of U.S. Provisional Application No. 62/165,258 filed on May 22, 2015, the entirety of which is incorporated by reference herein.

### BACKGROUND OF THE INVENTION

1. Field of the Invention

The present invention relates to integrated circuit (IC) devices, and in particular it relates to a capacitor structure and a method for forming the same.

2. Description of the Related Art

Capacitors are critical components in the integrated circuit devices of today. Both polysilicon and metal-oxide-metal capacitors have been used. Metal-oxide-metal (MOM) capacitors have been increasing in popularity because their minimal capacitive loss to the substrate results in a high-quality capacitor.

Metal-oxide-metal (MOM) capacitors have particularly been used extensively in the fabrication of, for example, integrated analog and mixed-signal circuits and power circuits on semiconductor dies. A MOM capacitor typically includes an oxide dielectric situated between adjacent metal plates. Conventionally, MOM capacitors are fabricated on semiconductor dies during back-end-of-line (BEOL) processing.

However, the miniaturization of components impacts all aspects of the processing circuitry, including the transistors and other reactive elements in the processing circuitry, such as capacitors. It is desirable in principle to fabricate MOM capacitors having similar and/or even higher capacitances as miniaturization of the size of MOM capacitors continues.

### BRIEF SUMMARY OF THE INVENTION

An exemplary capacitor structure comprises a semiconductor structure, a first interdigitated conductive element formed over a portion of the semiconductor structure, a second interdigitated conductive element formed over another portion of the semiconductor substrate, and a dielectric layer formed between the first and second interdigitated conductive elements. In one embodiment, the first interdigitated conductive element that is formed comprises a first base portion and a plurality of first protrusion portions having a first end connected with the first base portion and a second end not connected with the first base portion. In another embodiment, the second interdigitated conductive element comprises a second base portion and a plurality of second protrusion portions having a third end connected with the second base portion and a fourth end not connected with the second base portion. The plurality of second protrusion portions of the second interdigitated conductive element are interleaved with the plurality of first protrusion portions of the first interdigitated conductive element.

An exemplary method for forming a capacitor structure comprise removing portions of a conductive layer from a semiconductor structure, so that it forms interleaving first and second interdigitated conductive elements over different portions of the semiconductor structure. Furthermore, the method comprises forming a dielectric layer between the first and second interdigitated conductive elements. In one embodiment, the first interdigitated conductive element comprises a first base portion, and a plurality of first protrusion portions having a first end connected with the first base portion and a second end not connected with the first base portion. In another embodiment, the second interdigitated conductive element comprises a second base portion and a plurality of second protrusion portions having a third end connected with the second base portion and a fourth end not connected with the second base portion. The plurality of second protrusion portions of the second interdigitated conductive element are interleaved with the plurality of first protrusion portions of the first interdigitated conductive element.

Another exemplary method for forming a capacitor structure comprise providing a semiconductor structure with a planar conductive layer. The method further comprises patterning the planar conductive layer by scanning the planar conductive layer with a ray passing through a patterned photomask, and removing portions of the planar conductive layer from the semiconductor structure, forming interleaving first and second interdigitated conductive elements over different portions of the semiconductor structure. The method further comprises forming a dielectric layer between the first and second interdigitated conductive elements. In one embodiment, the first interdigitated conductive element comprises a first base portion, and a plurality of first protrusion portions, each having a first end connected with the first base portion and a second end not connected with the first base portion. The plurality of first protrusion portions of the first interdigitated conductive element has a rectangular configuration from a top view. The second interdigitated conductive element comprises a second base portion, and a plurality of second protrusion portions, each having a third end connected with the second base portion and a fourth end not connected with the second base portion. The plurality of second protrusion portions of the second interdigitated conductive element are interleaved with the plurality of first protrusion portions of the first interdigitated conductive element and the plurality of second protrusion portions of the second interdigitated conductive element has a rectangular configuration from a top view.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a top view of a capacitor structure according to an embodiment of the invention;

FIG. 2 shows a cross-sectional view of the capacitor structure along the line 2-2 in FIG. 1;

FIG. 3 is schematic top view showing an intermediate stage of a method for forming a capacitor structure according to an embodiment of the invention;

FIG. 4 shows a schematic cross-sectional view showing the capacitor structure along the line 4-4 in FIG. 3;

FIG. 5 is schematic top view showing an intermediate stage of a method for forming a capacitor structure according to an embodiment of the invention;

FIG. 6 shows a schematic cross-sectional view showing the capacitor structure along the line 6-6 in FIG. 5;

FIG. 7 is schematic top view showing an intermediate stage of a method for forming a capacitor structure according to an embodiment of the invention;

FIG. 8 is a schematic cross-sectional view showing the capacitor structure along the line 8-8 in FIG. 7; and

FIG. 9 is a schematic flowchart showing a method for forming a capacitor structure according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

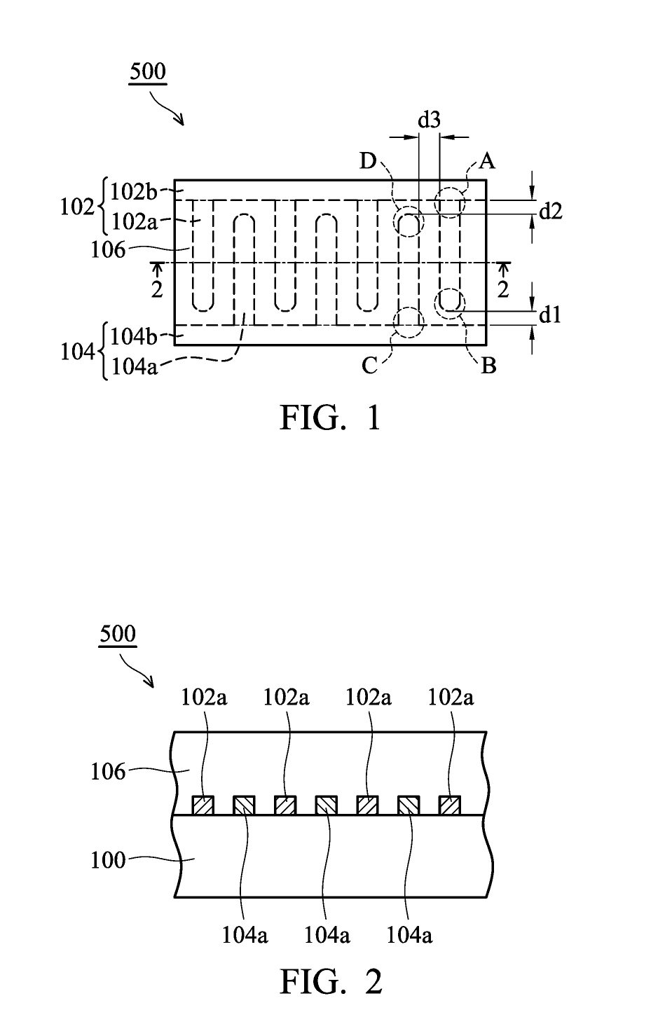

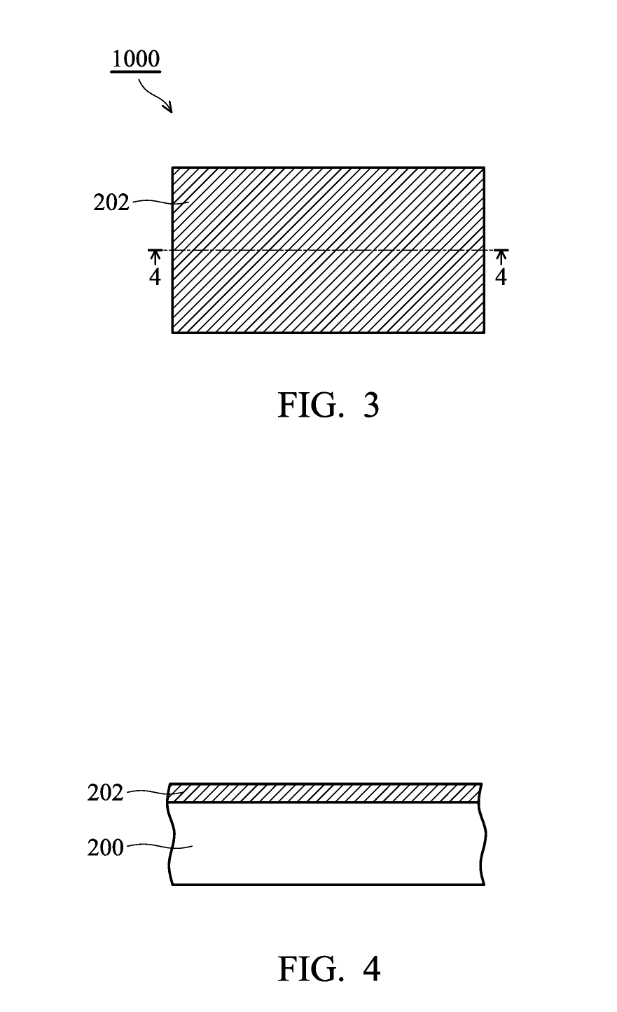

FIGS. 1-2 are schematic diagrams showing an exemplary capacitor structure 500. FIG. 1 shows a top view of the capacitor structure 500, and FIG. 2 shows a cross-sectional view of the capacitor structure 500 along the line 2-2 in FIG. 1.

As shown in FIG. 1, the capacitor structure 500 comprises a first interdigitated conductive element 102 and a second interdigitated conductive element 104 formed over different portions of a semiconductor structure 100 (not shown in FIG. 1, see FIG. 2). The first interdigitated conductive element 102 is interleaved with the second interdigitated conductive element 104, and a dielectric layer 106 is formed between and over the first interdigitated conductive element 102 and the second interdigitated conductive element 104. In one embodiment, the first interdigitated conductive element 102 shown in FIG. 1 may comprise a first base portion 102b and a plurality of first protrusion portions 102a. Each of the first protrusion portions 102a may comprise a first end A connected with the first base portion 102b and a second end B not connected with the first base portion 102b. Similarly, the second interdigitated conductive element 104 may comprise a second base portion 104b and a plurality of second protrusion portions 104a. Each of the second protrusion portions 104a may comprise a third end C connected with the second base portion 104b and a fourth end D not connected with the second base portion 104b. The first interdigitated conductive element 102 and the second interdigitated conductive element 104 may function as the electrode plates of the capacitor structure 500.

For the purpose of easier understanding, in one embodiment, the semiconductor structure 100 of the capacitor structure 500 shown in FIG. 2 is illustrated as a planar semiconductor structure and it may comprise a semiconductor substrate (not shown), a plurality of semiconductor devices (not shown) with the functions of, for example, active devices (e.g. transistor) or passive devices (e.g. capacitors, inductors, resistors) formed in and/or over the semiconductor substrate, and a plurality of interconnecting elements (e.g. conductive lines and conductive vias) made of a plurality of conductive layers (not shown) and insulating layers (not shown) formed over the semiconductor substrate.

As shown in FIGS. 1 and 2, the first interdigitated conductive element 102 and the second interdigitated conductive element 104 may comprise conductive materials such as aluminum, copper, or alloys thereof, and may be simultaneously formed during back-end-of-line (BEOL) processing. In one embodiment, the first interdigitated conductive element 102 and the second interdigitated conductive element 104 may be formed by following the exemplary processing steps (1)-(6):

(1) forming a conductive layer (a blanket layer comprising the first interdigitated conductive element 102 and the second interdigitated conductive element 104) over the semiconductor structure 100;

(2) forming a photoresist layer (not shown) over the conductive layer;

(3) performing a photolithography process (not shown) to expose portions of the photoresist layer by use of a patterned photomask comprising a transparent substrate and patterned opaque patterns (both not shown) formed on the transparent substrate. The opaque patterns are similar to the patterns of the first interdigitated conductive element 102 and the second interdigitated conductive element 104;

(4) developing the photoresist layer and removing the unexposed/exposed portions of the photoresist layer, thereby forming a patterned photoresist layer and exposing portion of the conductive layer;

(5) performing an etching process to remove portions of the conductive layer exposed by the patterned photoresist layer to form the first interdigitated conductive element 102 and the second interdigitated conductive element 104; and

(6) removing the patterned photoresist layer.

Since the first interdigitated conductive element 102 and the second interdigitated conductive element 104 are formed by the photolithography and etching processes described above, the second end B of the first protrusion portions 102a of the first interdigitated conductive element 102 and the fourth end D of the second protrusion portions 104a of the second interdigitated conductive element 104 are formed with a rounded configuration from the top view, which is a pattern deformation typically found during the photolithography process, while transferring the patterns on the patterned photomask to the photoresist layer and the conductive layer. For example, the second end B of the plurality of first protrusions 102a should be kept at a distance d1 of about 23 nm from the second base portion 104b, and the fourth end D of the plurality of second protrusions 104a should be kept at a distance d2 of about 23 nm from the first base portion 102b, to prevent undesired short-circuits from happening between the first interdigitated conductive element 102 and the second interdigitated conductive element 104. Similarly, one of the plurality of second protrusion portions 104a should be kept at a distance d3 of about 23 nm from one of the plurality of first protrusion portions 102a adjacent thereto, to prevent undesired short-circuits from happening between the first interdigitated conductive element 102 and the second interdigitated conductive element 104. It is noted that the dimension (such as the distance, 23 nm) is for conveniently describe the embodiment, not for a limitation.

Since the distances described above should be kept between the first interdigitated conductive element 102 and the second interdigitated conductive element 104 to prevent undesired short-circuits from happening in the capacitor structure 500, the capacitance of the capacitor structure 500 is limited and can be maintained or increased further by reducing the distance between the first interdigitated conductive element 102 and the second interdigitated conductive element 104 therein, as miniaturization a semiconductor device comprising the capacitor structure 500 continues.

Accordingly, a capacitor structure having increased capacitance by reducing the distance between the electrode plates therein is needed.

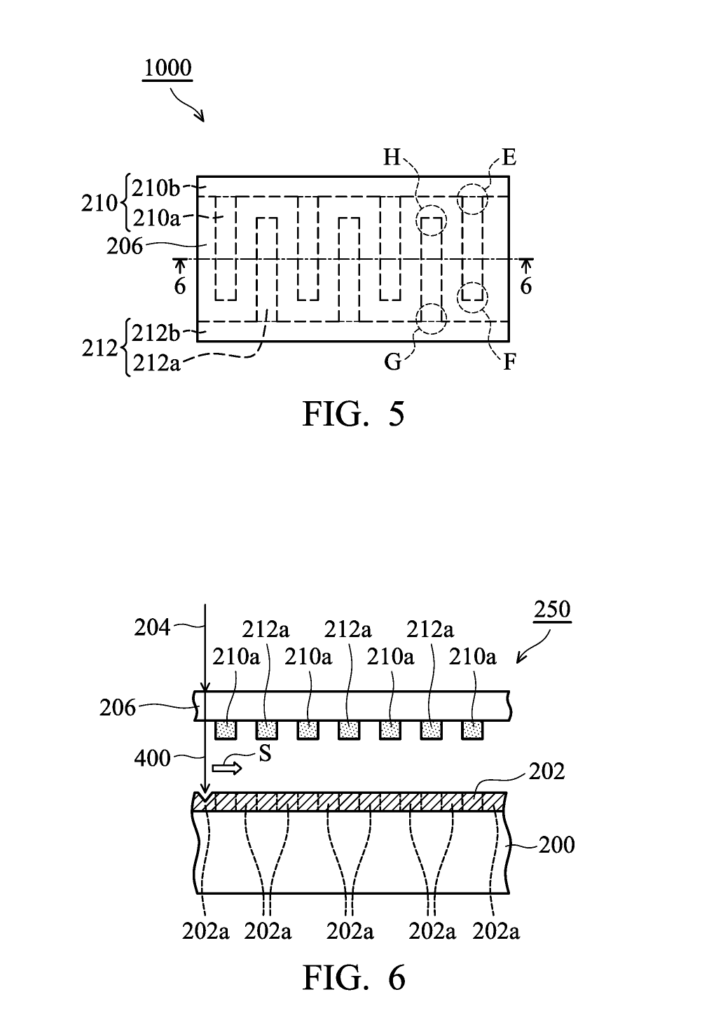

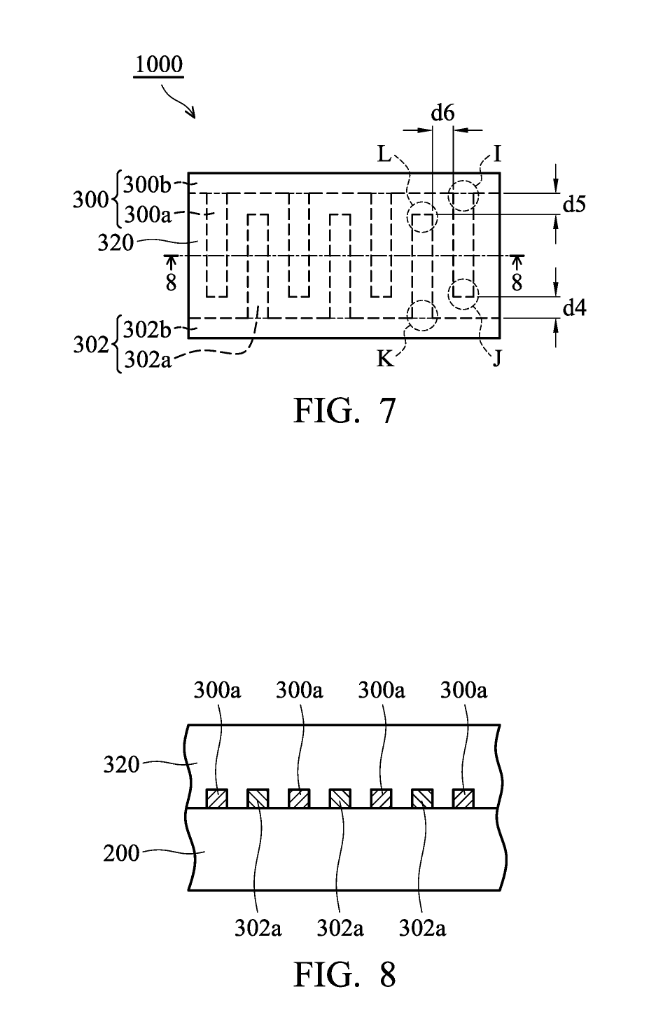

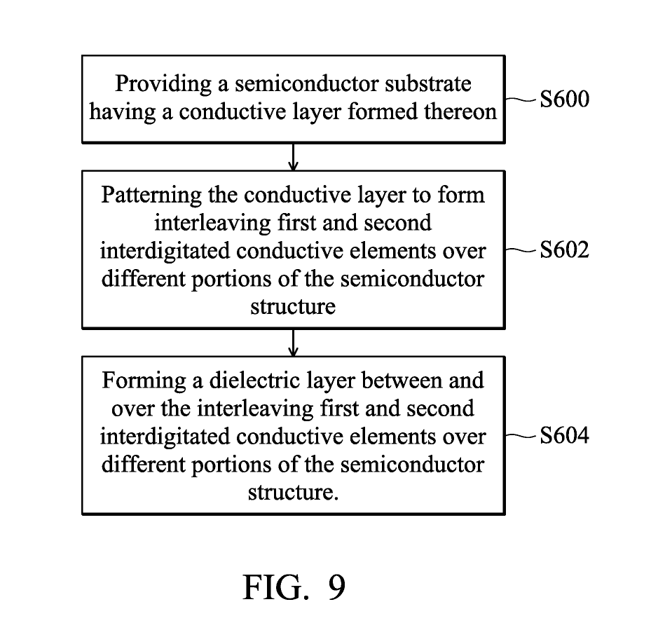

FIGS. 3-8 are schematic diagrams showing an exemplary method for forming a capacitor structure 1000 with increased capacitance by reducing the distances between the electrode plates therein. FIG. 4 shows a schematic cross-sectional view showing the capacitor structure along the line 4-4 in FIG. 3, FIG. 6 shows a schematic cross-sectional view showing the capacitor structure along the line 6-6 in FIG. 5, and FIG. 8 is a schematic cross-sectional view showing the capacitor structure along the line 8-8 in FIG. 7. In addition, FIG. 9 is a schematic flowchart related to the method for forming the capacitor structure 1000 shown in FIGS. 3-8 according to an embodiment of the invention.

As shown in FIGS. 3, 4, and 9, in step S600, a semiconductor substrate having a conductive layer formed thereon is provided. In one embodiment, a semiconductor structure 200 having a conductive layer 202 formed over it is provided. In one embodiment, the semiconductor structure 200 of the capacitor structure 1000 shown in FIG. 4 is illustrated as a planar semiconductor structure and it may comprise a semiconductor substrate (not shown), a plurality of semiconductor devices (not shown) with the functions of, for example, active devices (e.g. transistors) or passive devices (e.g. capacitors, inductors, resistors) formed in and/or over the semiconductor substrate, and a plurality of interconnecting elements (e.g. conductive lines and conductive vias) made of a plurality of conductive layers (not shown) and insulating layers (not shown) formed over the semiconductor substrate. In addition, the conductive layer 202 is formed over the semiconductor structure 200, having a thickness of about 1000 nm, and may comprise conductive materials such as aluminum, copper or alloys thereof.

Next, as shown in FIGS. 5, 6 and 9, in step S602, the conductive layer is patterned to form interleaving first and second interdigitated conductive elements over different portions of the semiconductor structure. In one embodiment, a patterned photomask 250 comprising a transparent substrate 206 and a plurality of opaque patterns 210 and 212 is provided over the semiconductor structure 200 and the conductive layer 202 shown in FIG. 6. A process 204 (see FIG. 5) is then performed to pattern the conductive layer 202 by scanning the conductive layer 202 with a ray 400 that passes through the transparent substrate 206 having opaque patterns 210 and 212 on it. As shown in FIG. 5, opaque patterns 210 and 212 are formed on the transparent substrate 206, and opaque patterns 210 and 212 are interdigitated patterns that are interleaved with each other. In one embodiment, the transparent substrate 206 may comprise quartz, and opaque patterns 210 and 212 may comprise chrome. In addition, opaque pattern 210 in FIG. 5 may comprise a first base portion 210b and a plurality of first protrusion portions 210a. Each of the first protrusion portions 210a may comprise a first end E connected with the first base portion 210b and a second end F not connected with the first base portion 210b. Similarly, opaque pattern 212 may comprise a second base portion 212b and a plurality of second protrusion portions 212a. Each of the second protrusion portions 212a may comprise a third end G connected with the second base portion 212b and a fourth end H not connected with the second base portion 212b. The opaque patterns 210 and 212 are patterns for patterning the conductive layer 202 and forming electrode plates in the conductive layer 202.

In process 204, for example, the ray 212a may comprise beam/pulse of electrons or light, and have an energy level over 0.5-20 Watt so that portions 202a of the conductive layer 202 exposed by opaque patterns 210 and 212 are directly etched and removed from the semiconductor structure 200 after being scanned by the ray 212 that passes through the photomask 206 that has opaque patterns 210 and 212 above the conductive layer 202 along the direction S. Therefore, after process 204, portions 202a of the conductive layer 202, which is shown in FIG. 6, are etched and removed, interleaving the first interdigitated conductive element 300 and the second interdigitated conductive element 302 and leaving them over different portions of the semiconductor structure 200, as shown in FIGS. 7-8.

In FIGS. 7-8, and 9, in step S604, a dielectric layer is formed between and over the interleaving first and second interdigitated conductive elements over different portions of the semiconductor structure. In one embodiment, a dielectric layer 320 is formed between and over first interdigitated conductive element 300 and second interdigitated conductive element 302. In FIG. 7, the first interdigitated conductive element 300 is interleaved with the second interdigitated conductive element 302, and a dielectric layer 320 is formed between and over the first interdigitated conductive element 300 and the second interdigitated conductive element 302. In one embodiment, the first interdigitated conductive element 300 shown in FIG. 7 may comprise a first base portion 300b and a plurality of first protrusion portions 300a. Each of the first protrusion portions 300a may comprise a first end I connected with the first base portion 300b and a second end J not connected with the first base portion 300b. Moreover, the second interdigitated conductive element 302 may comprise a second base portion 302b and a plurality of second protrusion portions 302a. Each of the second protrusion portions 302a may comprise a third end K connected with the second base portion 302b and a fourth end L not connected with the second base portion 302b. The first interdigitated conductive element 300 and the second interdigitated conductive element 302 may function as the electrode plates of the capacitor structure 1000. In one embodiment, the dielectric layer 320 may comprise dielectric materials such as silicon oxide, silicon oxynitride, or silicon nitride. In other embodiments, the dielectric layer 320 may comprise high-k dielectric materials having a dielectric constant over typically 1˜5.

In one embodiment, since the first interdigitated conductive element 300 and the second interdigitated conductive element 302 are patterned by process 204 shown in FIG. 6 rather than the photolithography and etching processes for forming the first interdigitated conductive element 102 and second interdigitated conductive element 104 shown in FIG. 1, such that no pattern deformation will be found in the first interdigitated conductive element 300 and the second interdigitated conductive element 302. Accordingly, the second end J of the first protrusion portions 300a of the first interdigitated conductive element 300 and the fourth end L of the second protrusion portions 302a of the second interdigitated conductive element 302 are formed with rectangular configuration from the top view and have an interior angle, such as about 90 degrees. In other embodiments, the interior angle can be other degrees, such as about 45 degrees (not shown). Thus, the first protrusion portions 300a of the first interdigitated conductive element 300 and the second protrusion portions 302a of the second interdigitated conductive element 302 have a substantially rectangular configuration from a top view.

For example, the second end J of the plurality of first protrusions 300a can be kept at a distance d4 of about 23 nm from the second base portion 302b, which is less than the distance d1 shown in FIG. 1. Similarly, the fourth end L of the plurality of second protrusions 302a can be kept at a distance d5 of about 23 nm from the first base portion 300b, which is less than the distance d2 shown in FIG. 1. One of the plurality of second protrusion portions 302a can be kept at a distance d6 of about 23 nm from one of the plurality of first protrusion portions 300a adjacent to it, which is less than the distance d2 shown in FIG. 1. Reduction of the above distances d4, d5, and d6 can be achieved by amending the distances between the opaque patterns 210 and 212 formed on the transparent substrate 206 as shown in FIGS. 5-6.

Therefore, since the above distances d4, d5, and d6 can be reduced further, the capacitance of the capacitor structure 1000 shown in FIGS. 7-8 can be increased further. This is true when compared with the capacitance of the capacitor structure 500 shown in FIGS. 1-2, while the first interdigitated conductive element 300 and the second interdigitated conductive element 302 shown in FIGS. 7-8, and the first interdigitated conductive element 102 and the second interdigitated conductive element 104 shown in FIG. 1, are formed with similar dimensions. The methods of forming the capacitor structure 1000 shown in FIGS. 3-8 are also applicable for forming a capacitor structure with maintained or further increased capacitance, as the miniaturization of semiconductor devices comprising capacitor structures continues. The capacitor structure 1000 with increased capacitance shown in FIGS. 7-8 can be provided in, for example, integrated analog, and mixed-signal circuits and power circuits on semiconductor dies.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A capacitor structure, comprising:
a semiconductor structure;
a first interdigitated conductive element formed over a portion of the semiconductor structure, comprising:
a first base portion; and
a plurality of first protrusion portions, each having a first end connected with the first base portion and a second end not connected with the first base portion;
a second interdigitated conductive element formed over another portion of the semiconductor substrate, comprising:
a second base portion; and
a plurality of second protrusion portions, each having a third end connected with the second base portion and a fourth end not connected with the second base portion, and the plurality of second protrusion portions of the second interdigitated conductive element are interleaved with the plurality of first protrusion portions of the first interdigitated conductive element;
and
a dielectric layer formed between the first and second interdigitated conductive elements.

2. The capacitor structure as claimed in claim 1, wherein the plurality of second protrusion portions of the second interdigitated conductive element and the plurality of first protrusion portions of first interdigitated conductive element have a rectangular configuration from a top view.

3. The capacitor structure as claimed in claim 1, wherein the dielectric layer is further over the first and second interdigitated conductive elements.

4. The capacitor structure as claimed in claim 1, wherein a top surface of the first interdigitated conductive element is coplanar with a top surface of the second interdigitated conductive element.

5. The capacitor structure as claimed in claim 1, wherein the first and second interdigitated conductive elements comprise aluminum, copper, or alloys thereof.

6. The capacitor structure as claimed in claim 1, wherein the dielectric layer comprises silicon oxide, silicon oxynitride, or silicon nitride.

7. The capacitor structure as claimed in claim 1, wherein the second end of the plurality of first protrusion portions has an interior angle of about 90 degrees.

8. The capacitor structure as claimed in claim 1, wherein the fourth end of the plurality of second protrusion portions has an interior angle of about 90 degrees.

9. A method for forming a capacitor structure, comprising:
removing portions of a conductive layer from a semiconductor structure, forming interleaving first and second interdigitated conductive elements over different portions of the semiconductor structure, wherein the first interdigitated conductive element comprising:
a first base portion; and
a plurality of first protrusion portions, each having a first end connected with the first base portion and a second end not connected with the first base portion;
and
wherein the second interdigitated conductive element comprises:
a second base portion; and
a plurality of second protrusion portions, each having a third end connected with the second base portion and a fourth end not connected with the second base portion, and the plurality of second protrusion portions of the second interdigitated conductive element are interleaved with the plurality of first protrusion portions of the first interdigitated conductive element;
and
forming a dielectric layer between the first and second interdigitated conductive elements.

10. The method as claimed in claim 9, wherein the plurality of second protrusion portions of the second interdigitated conductive element and the plurality of first protrusion portions of first interdigitated conductive element have a rectangular configuration from a top view.

11. The method as claimed in claim 9, wherein during formation of the dielectric layer, further comprising forming the dielectric layer over the first and second interdigitated conductive elements.

12. The method as claimed in claim 9, wherein a top surface of the first interdigitated conductive element is coplanar with a top surface of the second interdigitated conductive element.

13. The method as claimed in claim 9, wherein the first and second interdigitated conductive elements comprise aluminum, copper, or alloys thereof.

14. The method as claimed in claim 9, wherein the dielectric layer comprises silicon oxide, silicon oxynitride, or silicon nitride.

15. The method as claimed in claim 9, wherein the second end of the plurality of first protrusion portions has an interior angle of about 90 degrees.

16. The method as claimed in claim 9, wherein the fourth end of the plurality of second protrusion portions has an interior angle of about 90 degrees.

17. A method for forming a capacitor structure, comprising:
providing a semiconductor structure with a planar conductive layer;
patterning the planar conductive layer by scanning the planar conductive layer with a ray passing through a patterned photomask, and removing portions of the planar conductive layer from the semiconductor structure, forming interleaving first and second interdigitated conductive elements over different portions of the semiconductor structure, wherein the first interdigitated conductive element comprising:
a first base portion; and
a plurality of first protrusion portions, each having a first end connected with the first base portion and a second end not connected with the first base portion;
and
wherein the second interdigitated conductive element comprises:
a second base portion; and
a plurality of second protrusion portions, each having a third end connected with the second base portion and a fourth end not connected with the second base portion, and the plurality of second protrusion portions of the second interdigitated conductive element are interleaved with the plurality of first protrusion portions of the first interdigitated conductive element;
and
forming a dielectric layer between the first and second interdigitated conductive elements.

18. The method as claimed in claim 17, wherein the first and second interdigitated conductive elements comprise aluminum, copper, or alloys thereof.

19. The method as claimed in claim 17, wherein the dielectric layer comprises silicon oxide, silicon oxynitride, or silicon nitride.
